(19) United States
(12) Patent Application Publication
(10) Pub. No.: US 2024/0171093 A1
(43) Pub. Date: May 23, 2024

(54) ENERGY CONVERTER

(71) Applicant: Oxford University Innovation Limited, Oxford (GB)

(72) Inventors: Wenbin KANG, Oxford (Oxfordshire) (GB); John HUBER, Oxford (Oxfordshire) (GB)

(21) Appl. No.: 18/283,103

(22) PCT Filed: Feb. 18, 2022
(86) PCT No.: PCT/GB2022/050456

§ 371 Date: Sep. 20, 2023

(30) Foreign Application Priority Data
Mar. 23, 2021 (GB) 2104047.2

(51) Int. Cl. H02N 2/18; H02N 2/00

(52) U.S. Cl. CPC H02N 2/186; H02N 2/22

(57) ABSTRACT

A transducer is provided for converting mechanical energy to electrical energy. The transducer (100) comprises: a substrate (120); a ferroelectric element (110) adhered to the substrate (120); and a first and second electrode (114, 115) in electrical contact with the ferroelectric element (110). The first and second electrode (114, 115) are arranged to receive charge resulting from ferroelectric domain switching of the ferroelectric element (110) in response to mechanical loading of the transducer (100). The ferroelectric element (110) is partially polarised, so that a mechanical load cycle imposed on the transducer results in a reversible cycle of ferroelectric domain switching.

### FIELD OF INVENTION

The present invention relates to method of converting mechanical energy to electrical energy, and more specifically to an energy harvester.

### BACKGROUND

The last two decades have witnessed the rapid development of miniaturized portable electronics, including sensors, actuators and the internet of things, now widely found in daily life and industry. However, the resulting power demands are challenging for battery technologies and form a critical part of the compromise between lifetime, stability, capacity and the practical requirements of limited size for power sources. Therefore, energy harvesting transducers, which can turn ambient forms of energy into useful electrical power, have become attractive as an alternative or supplement to batteries in portable, remote and implantable devices.

A range of energy harvesting technologies have developed, generating electrical energy from ambient sources such as solar, thermal and mechanical/kinetic energy. These devices can save the cost and time associated with periodic recharging or replacement of batteries, and also improve sustainability. Given the ubiquitous presence in nature and artificial structures of mechanical vibrations, electromechanical energy harvesters using mechanical or kinetic energy created by vehicles, human motion, ocean waves, wind and fluids, have been widely investigated. There are various transduction mechanisms for converting mechanical/kinetic energy to electrical energy, including piezoelectric, electromagnetic, electrostatic and triboelectric approaches. Among these methods, piezoelectric energy harvesting has become widespread, and several researchers have attempted to optimise performance by employing materials with high piezoelectric coefficients or devising advantageous working modes. For example, piezoelectric materials have been developed with higher piezoelectric coefficient, or which are more convenient to process and apply.

The triboelectric effect is an alternative transduction mechanism for scavenging mechanical energy. Triboelectric nanogenerators have been proposed using Kapton and polyester as triboelectric layers.

Ferroelectric materials provide another promising material for energy harvesting. These materials have non-linear dielectric hysteresis relating electric field, stress, strain and electric displacement. The hysteresis arises due to ferroelectric or ferroelastic switching of domains, a process that can cause much greater charge flows than those found in piezoelectric transduction. Despite the potential of ferroelectrics for mechanical energy harvesting with high energy density, the challenges of nonlinearity, fatigue degradation and the difficulty of driving an electrical cycle by stress have limited their use in energy harvesting applications.

A problem with ferroelectric/ferroelastic energy harvesting is that an unpolarised material cannot be repolarised with stress alone. If mechanical loading is applied to an unpolarised random polycrystal of a ferroelectric, no polarisation will occur. If a polarised ferroelectric is depolarized using compressive stress, it cannot be repolarised using stress.

Theoretical designs of ferroelectric energy harvesters have been proposed¹ and modelled² theoretically which solve these problems by the application of a bias electrical field, which breaks the symmetry of the unpolarised state, and allows the action of stresses to drive a repolarization process that is effectively “directed” by the bias field. However, the use of a bias field is a design complication which may be disadvantageous in some contexts, because it requires additional electronic components to apply and control the bias field at the appropriate time in the stress cycle. ¹Kang, Wenbin, and John E. Huber. “Prospects for energy harvesting using ferroelectric/ferroelastic switching.” Smart Materials and Structures 28.2 (2019): 024002.²Behlen, Lennart, Andreas Warkentin, and Andreas Ricoeur. “Exploiting ferroelectric and ferroelastic effects in piezoelectric energy harvesting: theoretical studies and parameter optimization.” Smart Materials and Structures (2021).

Improvements to energy harvesting via the ferroelastic/ferroelastic effect are desirable.

### SUMMARY

According to an aspect of the invention, there is provided a transducer for converting mechanical energy to electrical energy, comprising:
a substrate;
a ferroelectric element adhered to the substrate;
a first and second electrode in electrical contact with the ferroelectric element and arranged to receive charge resulting from ferroelectric domain switching of the ferroelectric element in response to mechanical loading of the transducer;
wherein the ferroelectric element is partially polarised, so that a mechanical load cycle imposed on the transducer results in a reversible cycle of ferroelectric domain switching.

Arranging the ferroelectric element so that it is partially polarised may enable reversed ferroelastic switching without the need for an externally applied bias field during re-polarisation. In some embodiments the ferroelectric element may be under residual intrinsic stress (e.g. tensile) before the mechanical load cycle is applied. The reversible cycle of ferroelectric domain switching in response to the mechanical load cycle may not require the imposition of a bias field for repolarisation.

With no external load on the transducer, the ferroelectric element may be between 50% and 95% polarised.

With no external load on the transducer, the intrinsic tensile stress in the ferroelectric element may be sufficient to cause at least 5% depolarisation.

With no external load on the transducer, the intrinsic tensile stress in the ferroelectric element may be greater than the coercive stress for the material of the ferroelectric element. The intrinsic stress may be less than 5 times the coercive stress for the material of the ferroelectric element.

The intrinsic stress of the ferroelectric element may correspond with pre-poling the ferroelectric element so that it is partially polarised, adhering the ferroelectric element to the substrate, and then applying an electrical field greater than the coercive field for the ferroelectric element.

The intrinsic stress in the ferroelectric element may correspond with pre-poling the ferroelectric element to be between 20% and 95% polarised before it is adhered to the substrate.

The intrinsic stress may be tensile and the ferroelectric element may comprise a material with a negative d31.

The transducer may comprise a load path for external loads that impose a uniform bending moment on the substrate in the region of the ferroelectric material.

According to a second aspect, there is provided an energy harvesting device, comprising:
a transducer according to the first aspect (including any optional features thereof);
a top plate and a bottom plate;
wherein the top plate, bottom plate and substrate are configured to load the substrate so that forces that are applied between the top plate and bottom plate are converted into in-plane stress in the ferroelectric element.

According to a third aspect, there is provided an energy harvesting device, comprising:
a transducer according to the first aspect (including any optional features thereof);
a proof mass; and
a housing;
wherein the proof mass, housing and substrate are configured so that acceleration of the energy harvesting device results in inertial loading of the substrate.

The device may be configured such that loading (inertial or otherwise) of the substrate causes a bending moment that exerts a substantially uniform in-plane stress in the ferroelectric element.

The energy harvesting device according to either the second or third aspect may comprise a plurality of transducers according to the first aspect, arranged in a stacked configuration, so loading on one substrate is transferred to the other substrates comprised in the stack.

According to a fourth aspect, there is provided a method of preparing an energy harvesting transducer, comprising:
preparing a ferroelectric element attached to a substrate so that the ferroelectric element is partly polarised, so that a mechanical load cycle imposed on the transducer results in a reversible cycle of ferroelectric domain switching.

The ferroelectric element may be under residual stress (e.g. residual tensile stress) in addition to being partly polarised.

Preparing the ferroelectric element attached to a substrate may comprise:
partially pre-poling the ferroelectric material so that the material is partially polarised;
attaching the ferroelectric material to a substrate;
applying a field at least as large as the coercive field across the ferroelectric material after it is attached to the substrate, resulting in a residual stress in the ferroelectric material that prevents the ferroelectric material being fully polarised.

Preparing the ferroelectric element attached to a substrate may comprise:
elastically deforming a substrate so that at least a region of the substrate is under compressive stress;
attaching a ferroelectric element to the region of the substrate under compressive stress;
imparting tensile stress on the ferroelectric element as a result of relaxation of the compressive stress in the region of the substrate.

The ferroelectric material may be fully poled before the ferroelectric material is attached to the substrate.

Elastically deforming the substrate may comprise bending the substrate to cause sagging of a surface so as to impart compressive stress in a region adjacent the sagging surface, and
attaching the ferroelectric material to the substrate comprises attaching the ferroelectric material to the sagging surface.

The substrate may comprise more than one material with mismatched coefficients of thermal expansion, and the substrate may be configured to change shape in response to changes in temperature; and
elastically deforming the substrate may comprise changing the temperature of the substrate so that it changes shape.

According to a fifth aspect, there is provided a method of generating electrical power using a transducer, wherein:
the transducer comprises:
   a substrate;
   a ferroelectric element adhered to the substrate;
   a first and second electrode in electrical contact with the ferroelectric element and arranged to receive charge from resulting from ferroelectric domain switching of the ferroelectric element in response to mechanical loading of the transducer;
   and the ferroelectric element is partially polarised, so that a mechanical load cycle imposed on the transducer results in a reversible cycle of ferroelectric domain switching;
and the method comprises:
applying a mechanical load cycle to the transducer so as to generate electrical power into an electrical load by ferroelastic domain switching.

The mechanical load cycle may comprise a repolarisation phase in which the ferroelectric element becomes more polarised. The method may not include applying an electrical bias field during the repolarisation phase.

The transducer may be according to the first aspect.

The transducer may be comprised in an energy harvesting device according to the second or third aspect.

The transducer may have been prepared according to the fourth aspect.

Features of each aspect may be applied to each other aspect, as applicable. For example, the references to amounts of intrinsic stress and polarisation in the initial state (before stress cycling) in the first aspect may also be applicable to the other aspects. The method of the fourth aspect may be used to prepare a transducer or energy harvester according to any of the first, second or third aspects, including any of the optional features thereof.

### BRIEF DESCRIPTION OF THE DRAWINGS

FIG. 1 shows steps for preparing and load cycling a transducer according to an embodiment;

FIGS. 2 and 3 show transducer preparation steps and load cycling steps;

FIGS. 4 and 5 are graphs illustrating electric displacement vs electric field and stress vs strain respectively, for the steps illustrated in FIGS. 2 and 3;

FIG. 6 is a side view of an example embodiment, showing an example of how to make connections to top and bottom electrodes;

FIG. 7 shows an embodiment for quasi-static energy harvesting tests;

FIG. 8 shows an embodiment comprising a load impedance for cyclic energy harvesting;

FIGS. 9 to 11 are graphs obtained from quasi-static testing of a 30% pre-poled transducer, showing: electric displacement vs force; voltage vs charge; and force vs displacement respectively;

FIGS. 12 to 14 are graphs obtained from quasi-static testing of a 100% pre-poled transducer, showing: electric displacement vs force; voltage vs charge; and force vs displacement respectively;

FIGS. 15 and 16 are graphs showing energy output vs peak force for 30% pre-poled and 100% pre-poled transducers respectively;

FIGS. 17 to 19 respectively show the effect of the load cycle time on electric displacement vs force, voltage vs time and force vs displacement for 30% pre-poled and 100% pre-poled transducers;

FIGS. 20 to 22 respectively show voltage vs time, force vs displacement and electric displacement vs force for load cycling frequencies of 0.5 Hz, 5 Hz and 20 Hz;

FIGS. 23 to 25 respectively show voltage vs time, force vs displacement and electric displacement vs force with a load cycling frequency 20 Hz for 30% pre-poled and 100% pre-poled transducers.

FIGS. 26 and 27 respectively show peak voltage vs frequency and power vs frequency for load resistances of 1.1MΩ, 1.6MΩ, and 4.67MΩ;

FIGS. 28 to 30 respectively show voltage vs time, force vs displacement and voltage or power vs number of cycles with a load cycling frequency 20 Hz for 1^{st} cycle and 10^{5th} cycle;

FIG. 31 shows a comparison of power density vs frequency of load cycling for an example embodiment and some alternative devices of the prior art;

FIG. 32 shows an example energy harvester in which a top and bottom plate load the substrate in bending;

FIG. 33 shows an example energy harvester in which a top and bottom plate load a stack of transducers in bending; and

FIG. 34 shows an example energy harvester employing a proof mass to apply an inertial load to a transducer according to an embodiment.

### DETAILED DESCRIPTION

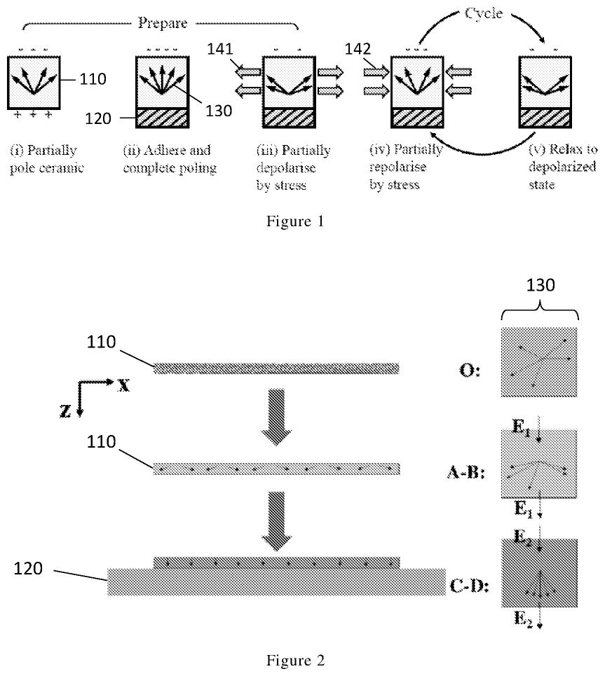

FIG. 1 shows example steps in preparing and then using a transducer according to an embodiment. The transducer comprises a ferroelectric element 110 bonded to a substrate 120.

The ferroelectric element 110 may comprise a relatively thin sheet or disc of material (sometimes referred to as a wafer), for example with a length and/or width that is at least 5 or 10 times the thickness. The ferroelectric element may be less than 1 mm thick, and at least 5 mm long. In some embodiments the ferroelectric element may be less than 0.5 mm thick.

For the purposes of this disclosure, the x direction corresponds with the length of the ferroelectric element, the y direction with the width of the ferroelectric element, and the z direction with the thickness of the ferroelectric element. References to “in-plane” should be understood to refer to the xy plane.

In the example method of FIG. 1, the ferroelectric element 110 starts in an unpolarised state: the local polarisation vectors of the individual domains are oriented randomly, so that the distribution of orientations comprises all directions. The polarisation state 130 in FIG. 1 (and subsequent drawings) is represented diagrammatically by arrows that indicate a distribution of domain polarisation vectors. In many suitable materials, polarising the ferroelectric element 110 so that the polarisation vector is oriented in the z direction results in a contraction of the ferroelectric element in the x direction (and y direction).

At step i) the ferroelectric element 110 is partially polarised, for example by the application of an electric field in the z direction below the coercive field for the material that comprises the ferroelectric element 110. In some embodiments the electric field applied during step i) may be at or above the coercive field, and switched off when the ferroelectric element reaches the desired degree of polarisation (i.e. when an amount of charge displacement reaches a desired value corresponding with a desired polarisation state). The ferroelectric element may, for instance, be between 20% and 50% polarised after step i). During step i) the ferroelectric element 110 is not attached to anything, so in-plane strain resulting from polarisation can relax without this generating stress in the ferroelectric element 110.

At step ii), the ferroelectric element 110 is bonded to the substrate 120 (e.g. with adhesive), and an electric field E_{z} is applied that is larger than the coercive field.

If the ferroelectric element 110 were still detached from the substrate 120, this would result in the ferroelectric element 110 being fully polarised. Since the ferroelectric element 110 is coupled to the substrate 120, strain eₓ induced by increasing polarisation is resisted by the substrate 120, resulting in tensile stress in the ferroelectric element in the x direction. Stress in the ferroelectric element 110 that is not a result of mechanical loading (e.g. of the substrate) may be referred to as intrinsic stress or residual stress.

Strain will also be induced in the y direction, but the effect of this biaxial stress (e.g. on the intrinsic stress in the x direction resulting from Poisson's ratio) will be ignored for the purpose of simplicity in this disclosure.

As illustrated in step iii) the intrinsic stress resulting from polarisation of the ferroelectric element results in a small amount of depolarisation (or to put it another way, the stress prevents the ferroelectric element from being fully polarised, even with an electric field that exceeds the coercive field).

At step iii) a further in-plane tensile stress may be applied to the ferroelectric element 110 to depolarise the material further (but this is not essential). One way to do this is to bend the substrate 120 to which the ferroelectric element is attached. Following step iii) the ferroelectric element is partially polarised, and under intrinsic tensile stress σₓ. The transducer can subsequently be used to harvest energy by converting a mechanical stress cycle in the ferroelectric element into electricity that can do work, as illustrated in steps iv) and v).

At step iv) the tensile stress in the ferroelectric element 110 is reduced by mechanical loading. One way to do this is to bend the substrate 120 to which the ferroelectric element 110 is bonded (in the opposite direction to that used to partially depolarise in step iii)), so that the resulting bending stress in the ferroelectric element is negative (i.e. compressive). The compressive stress resulting from bending will reduce the tensile stress σₓ in the ferroelectric element 110, which will result in an increase in polarisation. Relaxing the bending stress in the ferroelectric element 110 will result in partial depolarisation, as shown in step v). Charge displacement is associated with the change in polarisation state, and this movement of charge provides a source of electricity that can do work (e.g. providing power to a load, such as charging a battery etc).

In some embodiments, the stress cycle imposed on the ferroelectric element 110 may be purely compressive, so that effect of the loading is solely to impart a compressive stress cycle in the ferroelectric element 110. It may be preferable for the load to impart compressive stress, since compressive stress may be less damaging than tensile stress.

In other embodiments, the loading stress cycle may include imparting a cycle comprising both positive and negative stress on the ferroelectric element 110, or the loading stress cycle may comprise only tensile stress. The intrinsic stress in the ferroelectric element 110 may be adjusted to accommodate the intended load cycle.

The intrinsic stress and state of polarisation in the ferroelectric element may be selected to accommodate the expected load cycle without saturating polarisation (under compression) and without completely depolarising (under tension). The loading stress cycle may have an amplitude (i.e. magnitude of the difference between maximum stress and minimum stress) of between 25 MPa and 75 MPa. For example, a tensible load cycle may comprise imparting +50 MPa of stress and then unloading back to the intrinsic stress state. A compressive load cycle may comprise imparting −50 MPa of stress then unloading back to the intrinsic stress state. The intrinsic stress state may be between 0.5 MPa and 50 MPa, and more preferably between 1 MPa and 30 MPa. The degree of polarisation of the ferroelectric element at the start of the load cycle may be less than 95%, or less than 90% or between 20% and 95%, or between 50% and 95%.

Other methods may be used to prepare the transducer so that the ferroelectric element 110 is partially polarised and has intrinsic tensile stress. The applicant has found that partly pre-polarising the ferroelectric element 110 (so that it is 30% polarised) both avoids cracking of the ferroelectric element during the final poling (after it is bonded to the substrate) and provides good performance in conversion of mechanical work to electrical work (but other levels of pre-polarisation also work). In some embodiments, the ferroelectric element may be fully poled before it is attached to the substrate, and the substrate may be elastically deformed when the ferroelectric element is attached, so as to cause compression in a region of the substrate to which the ferroelectric element is attached. As the substrate relaxes, tensile stress will be imparted to the ferroelectric element, which will partially depolarise it. In some embodiments, an unpolarised ferroelectric element may be attached to the substrate, and subsequently partially poled, for example by using a field below the coercive field, or by applying a higher field for time is only sufficient to cause the required degree of polarisation.

In other embodiments the ferroelectric element 110 may be bonded to the substrate 120 while it is unpoled, and then polarised with an electric field E_{z} greater than the coercive field. Since the ferroelectric element 110 is constrained by the substrate, the in-plane strain (contraction) resulting from poling will be resisted, which will result in in-plane tensile stress, which will resist polarisation (to a greater extent than embodiments where the ferroelectric element is partially poled before bonding to the substrate). In embodiments where ferroelectric element 110 is unpoled when it is attached to the substrate, a compressive load may be applied to the ferroelectric element 110 during poling, to avoid the ferroelectric element cracking during poling.

Any suitable approach can be used to produce a ferroelectric material that is bonded to a substrate, partially polarised (e.g. between 20% and 95% polarised, or between 50% and 95% polarised), and which has an in-plane tensile stress (e.g. which may be material dependent, but which may be between 10 MPa and 50 MPa and/or typically less than 30 MPa).

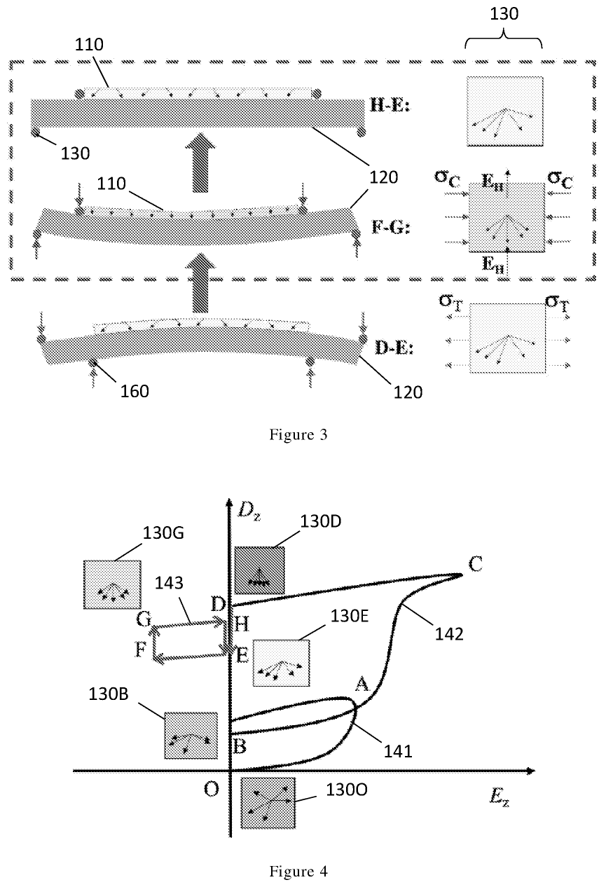

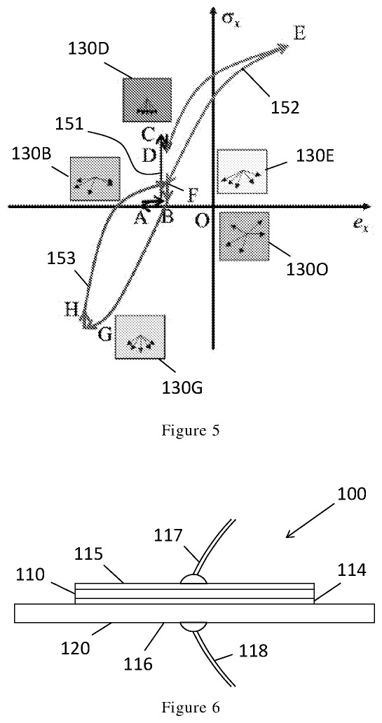

FIGS. 2 to 5 provide further illustration of an example method of transducer preparation. FIGS. 2 and 3 show views of the transducer (comprising substrate 120 and ferroelectric element 11) and the polarisation state 130 of the ferroelectric element 110 at various stages of preparation OABCDE and cycling FGHE. FIG. 4 shows electric displacement D, versus electric field E_{z} and FIG. 5 shows stress σₓ versus strain e_{.}

Initial pre-poling OAB results in electric displacement in the z direction, and negative in plane strain (i.e. the ferroelectric element 110 contracts in the xy plane). Since the ferroelectric element 110 in unconstrained, this pre-poling strain does not result in any in-plane stress. In this pre-poled state, the ferroelectric element 110 is adhered to the substrate 120. Further poling BCD is applied to produce a nearly fully polarised state with in-plane tensile stress. A further tensile stress DE is imparted to the ferroelectric element 110 to further depolarise the ferroelectric element 110, in this example by bending the substrate 120 under four point load. The four point load imparts a constant bending moment between the inner loading pins, and thereby imparts a uniform in-plane stress state to the ferroelectric element 110.

After preparation the energy harvesting cycle EFGH can be applied. In FIGS. 4 and 5 a quasi-static cycle is shown (for simplicity), in which a controlled voltage is between electrodes on the top and bottom of the ferroelectric element 110. The controlled voltage is used to impart step changes in electric field E_{z} during stages EF, where the field changes state to “on” and GH, where the field changes state to “off”. While the field is “on”, during stage FG, mechanical loading produces compressive stress σₓ in the ferroelectric element, causing it to repolarise. This produces a displacement current, which does electrical work against the applied electric field. In stage HE the electric field is “off” and the applied mechanical loading is removed, allowing ferroelastic switching to return the cycle to its initial state. The area of quadrilateral EFGH in FIG. 4 represents the output electrical work per unit volume of active material in a single cycle, while the corresponding area in FIG. 5 is an input mechanical work per unit volume. In practical applications in which the mechanical load is a load cycle at frequency, a similar electric field may result from the resistance of the load, which changes only details of the cycle: the basic features are the same.

An example transducer 100 for energy harvesting is shown in FIG. 6, comprising: substrate 120, ferroelectric element 110, adhesive/bottom electrode 114, top electrode 115, bottom wire 118, and top wire 117.

In this example the ferroelectric element consists of 8/65/35 PLZT (lanthanum doped lead zirconate titanate). It is not essential that this particular material is used, and in other embodiments any ferroelectric material that exhibits ferroelastic switching may be used. The selected material, with 8% lanthanum substitution into a 65% lead zirconate and 35% lead titanate solid solution, has the advantages of low coercive field (0.36 MV/m) and a soft composition allowing ferroelastic switching at stresses of a few MPa. The material has a rhombohedral-tetragonal morphotropic structure, and fine grain size (˜1 μm), which is advantageous in enhancing fracture toughness. The Curie temperature is 110 degrees C. and the maximum polarization at room temperature is 0.25 C/m².

The substrate 120 in the example of FIG. 6 comprises a tool-steel substrate with thickness 1 mm. The ferroelectric element 110 comprises a PLZT wafer with thickness 0.33 mm, adhered to the substrate with conductive adhesive 114. A top electrode 115 may be formed using any suitable conductor, such as a thin coating of conductive paint. The top wire 117 is electrically connected to top electrode 115 using conductive epoxy. Since the substrate 120 in this case is conductive, the bottom wire 118 in this example is connected to the substrate 120 using conductive epoxy, and the substrate forms the electrical connection between the conductive epoxy and the bottom electrode 114. The thickness of the top electrode 115 and conductive adhesive 114 are (mechanically) essentially negligible.

The substrate dimensions 120 in the example were 68×4×1 mm with the ferroelectric element covering a central portion of length 38 mm. Other dimensions can be used in other embodiments, and the dimensions and material comprising the substrate and ferroelectric element will depend on the application. For example a natural frequency of a transducer (or energy harvesting device comprising the transducer) may be configured to coincide with the frequency of a mode of vibration of a system from which energy is to be harvested.

For the example ferroelectric element, the charge displacement corresponding with complete poling is 0.25 C/m². A reference to partially poling the material in this disclosure is a reference to the fraction of electric displacement, relative to the electric displacement associated with complete poling.

Example embodiments were fabricated, with the degree of pre-poling (i.e. step i) in the process depicted in FIG. 1) at 100%, 75%, 50% and 30%. Once adhered to the steel substrate described above, the ferroelectric element was fully poled (to 0.25 C/m²).

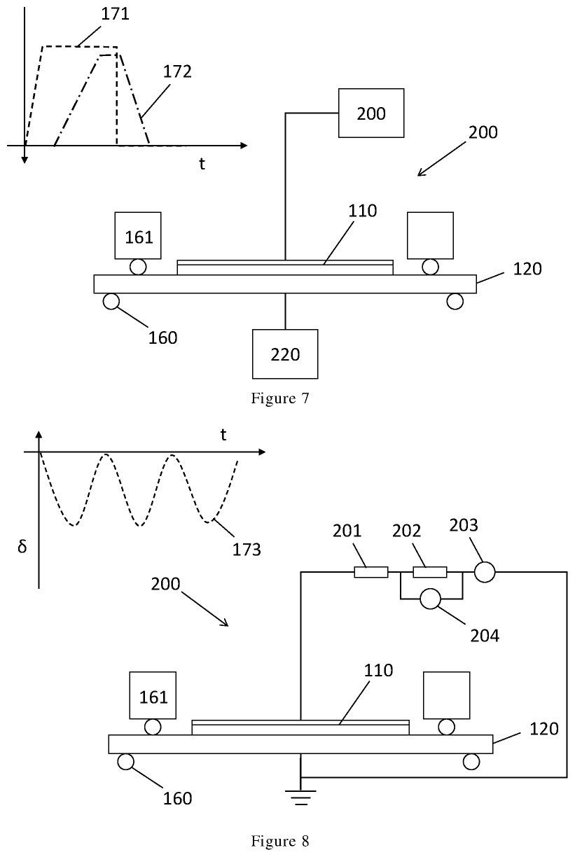

Example test arrangements are shown in FIGS. 7 and 8.

FIG. 7 shows a test arrangement for quasi-static testing of the energy harvesting cycle. Mechanical loading was carried out using a four point loading microtest system. The substrate 120 was connected to ground via a capacitive electrometer 220. At the top electrode, voltage was controlled via voltage controller 200. The voltage 171 and load 172 over time are schematically depicted in the inset graph. A steady voltage opposing the charge flow is applied via the top and bottom electrodes as bending load is imparted to the substrate 120, in order to simulate an electrical load. This voltage was removed during mechanical unloading of the substrate 120. In FIG. 7 the force and electrical field are both negative, with the force configured to impart compression on the ferroelectric element 110 as a result of the bending moment imparted to the substrate 120, and the electrical field positive direction defined as upward. Each pair of loading pins 161 was placed 5 mm apart, on either side of the ferroelectric element 110. Load was imparted directly to the substrate 120.

FIG. 8 shows an example embodiment suitable for testing energy harvesting under cyclic load. Cyclic mechanical loading was applied via a similar four point loading fixture (to FIG. 7). Displacement 6 of the loading pins was monitored, which is proportional to the bending moment imparted on the substrate (which is in turn, proportional to the stress imparted on the ferroelectric element 110). The inset graph shows an example trace 173 of displacement vs time.

The top electrode was connected to a load resistor 201 and monitoring resistor 202. The load resistor 201 and monitoring resistor 202 together form a potential divider, and the voltage dropped over the monitoring resistor 202 allows the voltage at the top electrode to be inferred. The substrate 120 was connected to ground. A capacitive electrometer 203 was used to measure charge flow. Voltages at the electrometer 203 were kept at the mV level to avoid offsetting the top electrode voltage, and which was typically 1 to 50V (in magnitude). The load resistor 201 was varied in the range 3 kΩ to 15MΩ, and the operating frequency varied from 0.5 Hz to 20 Hz. Runs of 0.5×10⁶ cycles were used to test for stability and fatigue.

In quasi static loading, the transducer was tested by applying the following cycle:
i) Apply voltage Vₐₚₚ to the top electrode with the bottom electrode grounded (via the substrate in the example embodiment, but this is not essential, and a non-conductive substrate can be used). The applied voltage is selected to produce an electrical field αE₀ where E₀ is the coercive field (which was 0.36 MV/m in this case) and a is a factor that can be varied to simulate different electrical loads.
ii) With the electrical field held constant, apply a mechanical loading force F/2 to each pin (upwards on the lower pins, and downwards on the upper pins). This force drives in-plane compression of the ferroelectric element 110, and an increase in net polarisation within the ferroelectric element 110.
iii) With the loading pins held fixed (i.e. at constant loading), reduce the applied voltage to zero.
iv) Reduce the mechanical load to zero.

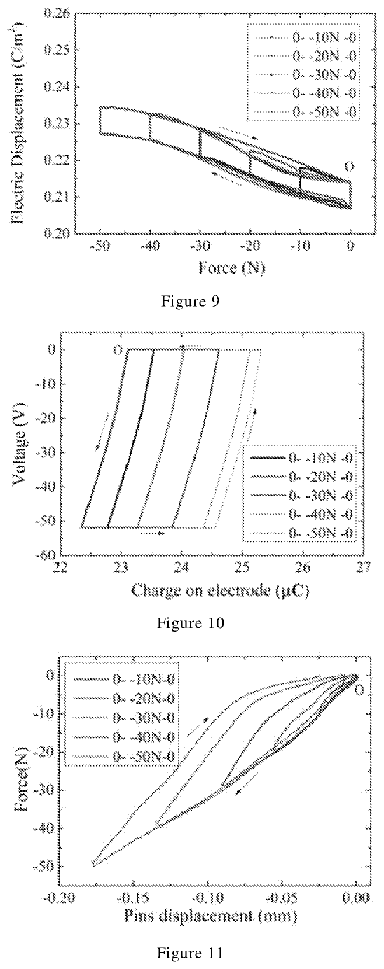

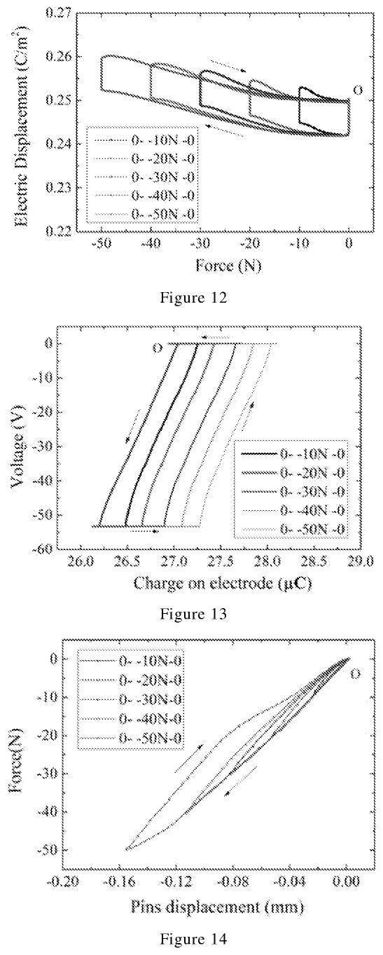

The quasi static cycle was traversed at a frequency of 10⁻² Hz. FIGS. 9 to 14 show the results of testing at a range of force values F, varying from −10N to −50N. FIGS. 9 to 11 show results for 30% pre-poled, and FIGS. 12 to 14 show results for 100% pre-poled. For the example embodiment tested, 50N corresponds with a compressive stress of −50 MPa to −55 MPa in the ferroelectric element (bending stress being linearly proportional to the distance from the neutral axis).

FIG. 9 shows electric displacement against force for load cycles with different values of F. The vertical straight segments of each cycle correspond to changes in electric displacement at constant force, due to switching the electric field “on” or “off”; curved segments correspond to the application or removal of mechanical loading. The cycle is traversed in a clockwise direction, starting from 0, indicated on each of FIGS. 9 to 14 (and on other figures of similar load cycles). In each of FIGS. 9 to 14, α=−0.4 (Vₐₚₚ=−50V).

FIGS. 10 and 13 show voltage against the charge on the top electrode, and comprise horizontal straight segments, due to the application or removal of mechanical load at constant voltage. The curved segments in FIGS. 10 and 13 show the variation of charge at the top electrode as the electric field is switched. Here the cycle is traversed in an anti-clockwise direction.

In the 100% pre-poled sample (shown in FIGS. 12 to 14), very little ferroelastic switching occurs when the mechanical load is applied because the starting state is close to a saturated, fully polarized state. The magnitude of the electric displacement changes during mechanical loading with a fully polarised starting state is less than 10⁻² C/m², comparable with what is typically achieved in piezoelectric energy harvesting. By comparison, the cycles shown in FIGS. 9 to 11 for the 30% pre-poled sample are similar in character (to those of FIGS. 12 to 14), but with much greater changes in electric displacement when mechanical loading is applied. This is consistent with ferroelastic switching caused by the mechanical loading. The cycle for the 30% pre-poled sample starts with a polarization of about 0.21 C/m², so there is freedom for the polarization to increase under mechanical loading. The enclosed area in the voltage-charge loops indicates the electrical energy output per cycle of loading. This is more than twice as great in the 30% pre-poled case than in the 100% pre-poled case, indicating the importance of the preparation of the ferroelectric element into a partially polarised and tensile stressed before the loading cycle (in this case, by the partial poling process, but other techniques can also be used). The input mechanical energy can be ascertained from the enclosed area in the force-displacement curves of FIGS. 11 and 14. The enclosed area is larger with greater applied load amplitude and is much greater in the 30% pre-poled case.

The results shown in FIGS. 9 to 14 clearly demonstrate a working cycle for the ferroelectric/ferroelastic energy harvester. There are several compromises to consider in order to achieve optimal performance: increasing the electric field by controlling α enhances the energy output per cycle, but if the field strength becomes too high it may cause ferroelectric switching and destroy the delicately engineered state of the energy harvester. For this reason, experimentation was constrained by α>−0.4. Similarly, increasing the total applied force F increases the energy per cycle, but again high values may disturb the material state by irreversible ferroelastic switching, or may promote fatigue.

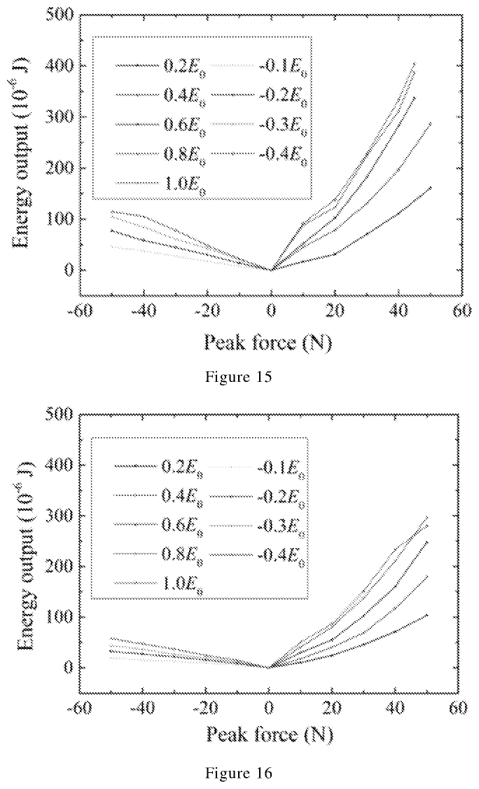

FIG. 15 summarises the energy output per cycle from a set of tests in which α and F were varied in 30% pre-poled samples, and FIG. 16 shows results from a 100% pre-poled sample. The tests with F>0 indicate cases where the sample was inverted in the loading fixture in order to produce in-plane tensile stresses in the active layer.

FIGS. 15 and 16 clearly show that the 30% pre-poled case consistently produces greater energy output per cycle than the 100% pre-poled case. The 30% pre-poled sample generated 1200 per cycle with F=−50N and α=−0.4, which is much greater than that of typical piezoelectric energy harvesters of the same size. Even greater energy yields were achieved in tests with in-plane tension (i.e. working cycles that impart tension, rather than compression to the ferroelectric element). However, loading the ferroelectric in tension was observed to cause cracking in some cases, specifically, for α>0.8 and F=50N. Because the PLZT layer was translucent, the formation of cracks could be observed as lines of dark contrast when the sample was back-lit.

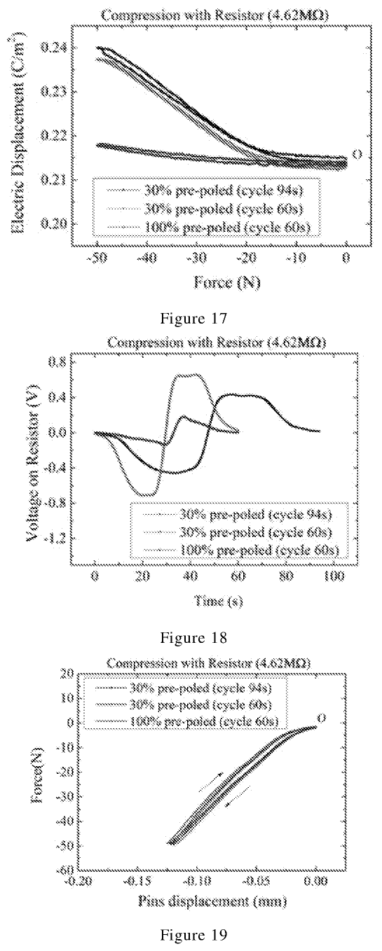

In practical applications, it may not be practical to control the voltage on the top electrode directly, but instead an external load will be connected, and the impedance of the external load will control the voltage on the top electrode. To simulate this working condition, quasi-static tests were carried out for the case F=−50N with a 4.62MΩ external load resistor 202 (see FIG. 8). FIGS. 17, 18 and 19 compare the results obtained from 100% and 30% pre-poled ferroelectric elements. The 30% pre-poled ferroelectric element was also tested using two different cycle times (94 s and 60 s).

FIG. 17 shows force versus electric displacement cycles, in which the 30% pre-poled sample produces much greater, and more non-linear, changes in electric displacement compared to the 100% pre-poled case. This further confirms that ferroelectric/ferroelastic switching is occurring under load.

The cycle period has limited effect on the electric displacement changes but does affect the rate that charge is produced by the ferroelectric element, which in turn affects the voltage across the load resistor, since higher current flows result in greater voltage drops. This could result in complex interactions between the transducer and the external circuit if the electric field in the transducer approaches the coercive field. Hence control of the external electrical load and the cyclic frequency and amplitude of mechanical loading may be employed to establish a more stable energy harvesting cycle. The results obtained in FIGS. 17, 18 and 19 were obtained with a triangular mechanical waveform, and with voltages well below coercive levels, and it is evident that the shape of the waveform of the generated voltage is not triangular, and that the shape is dependent on the loading cycle frequency.

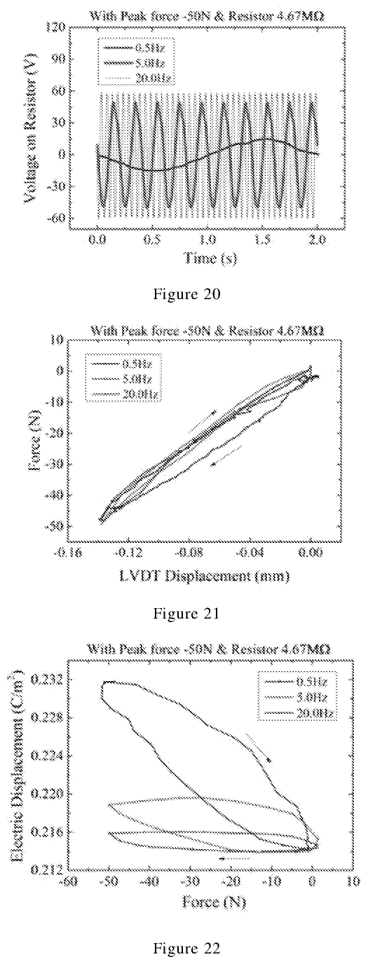

Human motion is an important potential source of mechanical energy for energy harvesting. Another important potential source of mechanical energy are vehicle vibrations. Generally, human motion generates vibrations in a frequency range 0.5 Hz-15 Hz, while 15 Hz-50 Hz vibrations are common in vehicles. To test the response of transducers according to embodiments at these frequencies, variations of pre-poling states, load resistor and frequency were explored, and the results are presented in FIGS. 20 to 30. The mechanical displacement waveform was sinusoidal in these tests.

FIGS. 20 to 22 present the effect of frequency on a 30% pre-poled energy harvester according to an embodiment, driven with 50N force amplitude in compression, and working against a 4.67MΩ electrical load. FIG. 20 shows voltage on the load resistor as a function of time, FIG. 21 shows force vs displacement, and FIG. 22 shows electric displacement vs force. FIG. 20 shows that the generated voltage amplitude increases with frequency, though the increase from 5 Hz to 20 Hz is only a few percent and further tests indicate that the generated voltage stabilizes as frequency increases. The generated voltage waveform is not sinusoidal, indicating non-linearity. The electric displacement changes during each cycle at 0.5 Hz (shown in FIG. 22) are slightly less in magnitude than the corresponding values in the quasi-static tests; the electric displacement amplitude reduces with increasing frequency. This is expected because high rates of electric displacement require high currents and hence high voltages, which in turn resist ferroelectric/ferroelastic switching. Thus the electrical load tends to stabilize the voltage amplitude and limit switching at higher frequencies.

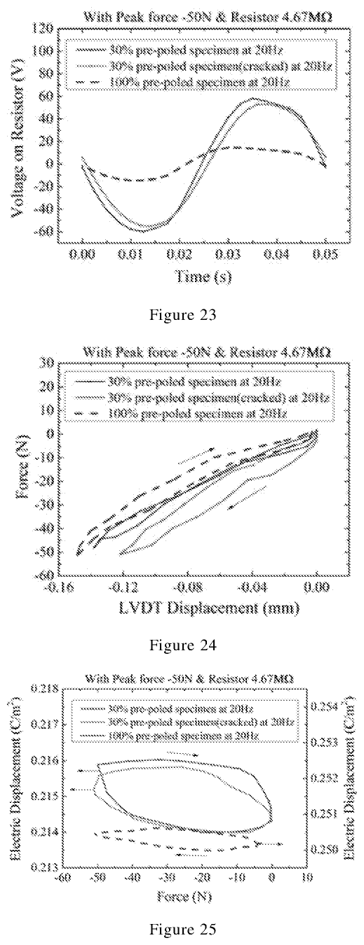

FIGS. 23 to 25 provide a performance comparison between the 30% pre-poled and 100% pre-poled energy harvesters at 20 Hz. FIG. 23 shows voltage on the load resistor as a function of time, FIG. 24 shows force vs displacement, and FIG. 25 shows electric displacement vs force. As with the quasi-static tests, the 30% pre-poled specimen demonstrates greater voltage and electric displacement amplitude—hence greater power output. As remarked earlier, some operating conditions cause the formation of cracks in the active layer, running perpendicular to the x-axis direction. However, these cracks did not appear to greatly affect energy harvesting performance. FIGS. 23 to 25 include results for a cracked and uncracked specimen (pre-poled at 30% polarisation). Tests were also carried out to establish whether the performance was sensitive to the sample preparation process. It was found that the results were repeatable across different samples, to within a few percent.

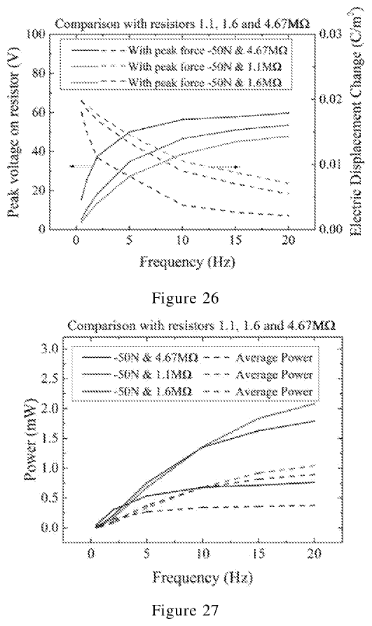

FIGS. 26 and 27 show the effect of different load resistance on peak voltage, electric displacement change and power. FIG. 26 shows peak voltage and electric displacement change versus frequency for three different load resistance values: 1.1 MΩ, 1.6MΩ and 4.67MΩ. The peak voltages increase monotonically with frequency, whereas the electric displacement amplitude decreases monotonically. Variation of the load resistor changes the RC time constant and hence affects power matching. This is seen in FIG. 27 where the 4.67MΩ load resistor achieves greatest power for frequencies less than 3 Hz, the 1.6MΩ achieves greatest power from 3-10 Hz, and then the 1.1MΩ resistor becomes preferable for frequencies greater than 10 Hz. Because the voltage waveform varies, the average power is not directly given, as for piezoelectric harvesters, by V²/2R. Instead, the average power values in FIG. 27 were computed by integration of the instantaneous power over the cycle. The average power shows a similar trend to the peak power data.

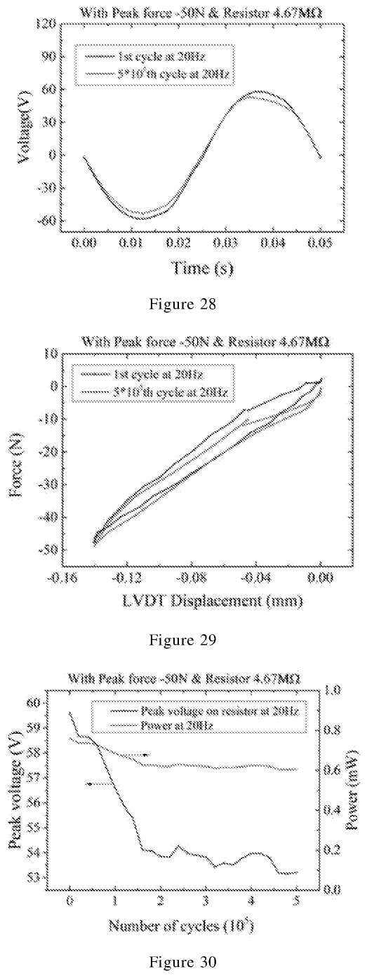

FIGS. 28 to 30 show the results of fatigue testing. A practical energy harvester should be able to operate over a high number of cycles without degradation. FIG. 28 shows a voltage versus time curve for the first cycle and the 5×10⁵th cycle. There is around a 10% drop in the voltage after 5×10⁵ cycles, corresponding with a 20% drop in peak power. FIG. 29 shows force versus displacement curves for first cycle and the 5×10⁵th cycle: the cycle is reasonably stable (showing the same 10% drop, but a consistent shape). FIG. 30 shows the effect of higher cycles (to 5×10⁵) on peak voltage. After 2×10⁵ cycles, the power output remains stable until 5×10⁵. No cracks were observed in the ferroelectric element over the testing. These results indicate that embodiments are capable of high cycle operation with acceptable performance.

FIG. 31 compares the results obtained using embodiments with results obtained from prior art energy harvesting approaches. FIG. 31 indicates that ferroelectric/ferroelastic energy harvesters according to embodiments compare favourably with a range of piezoelectric devices, offering greater cycle energy density and greater power. Embodiments remain effective at low frequencies typical of structural and mechanical vibrations, as well as human motion. Cycle energy density is comparable to triboelectric energy harvesters. It should be noted that some triboelectric devices are characterised by sliding velocity rather than operating frequency and the comparison with oscillating devices has been made by assuming an amplitude and calculating the frequency that provides the required peak velocity at that amplitude. The amplitude used for comparison purposes was the amplitude of displacement applied to the loading pins in our experiment. Specifically, the example ferroelectric energy harvester has a cycle energy density in the region of 2 mJ/cm³. Power output varies with frequency and was about 20 mW/cm³ at 20 Hz, the maximum frequency tested here.

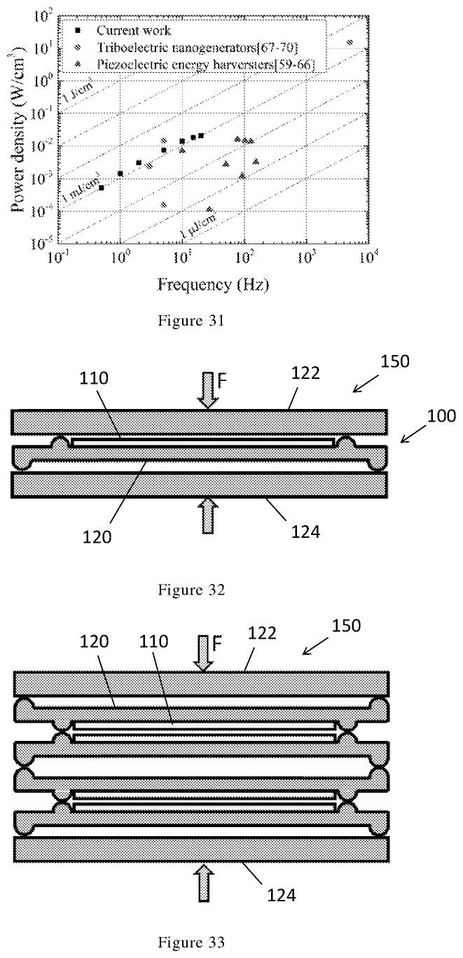

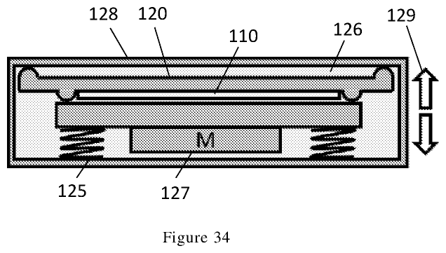

FIGS. 32 and 33 show examples of energy harvesters 150 according to embodiments that are arranged to receive loads applied to the energy harvester 150 into four point loading on the substrate 120 of the transducer 100.

In FIG. 32 the substrate 120 is provided with loading pins (which may be integral), and the energy harvester comprises a top plate 122 and bottom plate 124. The top and bottom plates 122, 124 transfer loads exerted on them to the loading pins provided as part of the substrate 120. In other embodiments the loading pins could be part of the top plate and/or bottom plate, rather than part of the substrate 120.

FIG. 33 shows an energy harvester 150 comprising: a top plate 122, bottom plate 124, and a stacked set of transducers, each comprising a substrate 120 and ferroelectric element 110. Each of the stacked substrates further comprises loading pins, and the energy harvester is configured so that the top plate and bottom plate 122, 124 transfer forces exerted on them into bending moments in each of the stacked substrates, via the loading pins. In this way each ferroelectric element is subjected to uniform bending stress as a result of loads placed on the energy harvester 150. The stacked devices may be connected in parallel to an electrical load (for increased current), or in series (for increased voltage).

FIG. 34 shows an inertial energy harvester, comprising: housing 128, substrate 120, ferroelectric element 110, proof mass 127 and pre-loading springs 125. The substrate is provided with loading pins, so that inertial loads from the proof mass (resulting from acceleration in the direction indicated by arrows 129) are converted into bending moment in the substrate 120, and consequently to bending stresses in the ferroelectric element 110. Pre-loading springs 125 may be provided to maintain the proof mass 127 in engagement with the substrate 120. The housing 128 encloses the transducer (comprising substrate 120 and ferroelectric element 110), proof mass 127 and pre-loading springs 127. Potting 126 may be provided within the housing 128 to hold all the components in place. The potting 126 may comprise a non-conducting soft elastomeric material, so that there is no interference with the mechanical operation of the transducer.

Transducers suitable for energy harvesting have been disclosed that use ferroelectric/ferroelastic switching effect to generate electrical energy from mechanical energy. Transducers according to certain embodiments are prepared so that they are partly polarised and subject to an intrinsic stress so that it is near to ferroelastic switching. Each subsequent stress cycle thereby causes reversible ferroelastic switching without the need for an external polarising field (beyond the inherent field that arises as a consequence of charge displacement when connected to a load impedance). Devices according to an embodiment provide higher power density than devices employing the piezoelectric effect, and are simpler to employ than prior are devices based on the ferroelastic effect. Embodiments are promising for a range of applications, including ambient energy harvesting from human movement, and energy harvesting from vehicle vibrational modes.

Although example embodiments have been described in which bending is the mode of mechanical loading of the substrate, this is not essential, and embodiments may employ uniaxial loading, or other modes of loading. Similarly, although the example embodiments describe a ferroelectric material which contracts in-plane with increasing polarisation (oriented normal to the plane), this is also not essential. A similar approach may be used to prepare ferroelectric materials with the opposite response, in which tensile intrinsic stress is replaced by compressive in-plane intrinsic stress.

The scope of the present invention is not intended to be limited by the example embodiments, but should be determined with reference to the accompanying claims.

1. A transducer for converting mechanical energy to electrical energy, comprising:
a substrate;
a ferroelectric element adhered to the substrate;
a first and second electrode in electrical contact with the ferroelectric element and arranged to receive charge resulting from ferroelectric domain switching of the ferroelectric element in response to mechanical loading of the transducer;
wherein the ferroelectric element is partially polarised, so that a mechanical load cycle imposed on the transducer results in a reversible cycle of ferroelectric domain switching.

2. The transducer of claim 1, wherein the reversible cycle of ferroelectric domain switching in response to the mechanical load cycle does not require the imposition of a bias field for repolarisation.

3. The transducer of claim 1, wherein the ferroelectric element has an intrinsic stress with no external load placed on the transducer.

4. The transducer of claim 1, wherein, with no external load on the transducer: i) the ferroelectric element is between 50% and 95% polarised and/or ii) an intrinsic tensile stress in the ferroelectric element is sufficient to cause at least 5% depolarisation.

5. (canceled)

6. The transducer of claim 1, wherein with no external load on the transducer, an intrinsic tensile stress in the ferroelectric element is greater than a coercive stress for the material of the ferroelectric element.

7. The transducer of claim 1, wherein the ferroelectric element has an intrinsic stress and the intrinsic stress of the ferroelectric element corresponds with pre-poling the ferroelectric element so that it is partially polarised, adhering the ferroelectric element to the substrate, and then applying an electrical field greater than the coercive field for the ferroelectric element.

8. The transducer of claim 7, wherein the ferroelectric element has an intrinsic stress and the intrinsic stress in the ferroelectric element corresponds with pre-poling the ferroelectric element to be between 20% and 95% polarised before it is adhered to the substrate.

9. The transducer of claim 1, wherein the ferroelectric element has an intrinsic stress and the intrinsic stress is tensile and the ferroelectric element comprises a material with a negative d31.

10. The transducer of claim 1, wherein the transducer comprises a load path for external loads that impose a uniform bending moment on the substrate in the region of the ferroelectric material.

11. The transducer of claim 1, configured as an energy harvesting device and further comprising:
a top plate and a bottom plate;
wherein the top plate, bottom plate and substrate are configured to load the substrate so that forces that are applied between the top plate and bottom plate are converted into in-plane stress in the ferroelectric element.

12. The transducer of claim 1, configured as an energy harvesting device and further comprising:
a proof mass; and
a housing;
wherein the proof mass, housing and substrate are configured so that acceleration of the energy harvesting device results in inertial loading of the substrate.

13-14. (canceled)

15. A method of preparing an energy harvesting transducer, comprising:
preparing a ferroelectric element attached to a substrate so that the ferroelectric element is partly polarised, so that a mechanical load cycle imposed on the transducer results in a reversible cycle of ferroelectric domain switching.

16. The method of claim 15, wherein preparing the ferroelectric element attached to a substrate comprises:
partially pre-poling the ferroelectric material so that the material is partially polarised;
attaching the ferroelectric material to a substrate;
applying a field at least as large as the coercive field across the ferroelectric material after it is attached to the substrate, resulting in a residual stress in the ferroelectric material that prevents the ferroelectric material being fully polarised.

17. The method of claim 15, wherein preparing the ferroelectric element attached to a substrate comprises:
elastically deforming a substrate so that at least a region of the substrate is under compressive stress;
attaching a ferroelectric element to the region of the substrate under compressive stress;
imparting tensile stress on the ferroelectric element as a result of relaxation of the compressive stress in the region of the substrate.

18. The method of claim 17, wherein the ferroelectric material is fully poled before the ferroelectric material is attached to the substrate.

19. The method of claim 17, wherein:
elastically deforming the substrate comprises bending the substrate to cause sagging of a surface so as to impart compressive stress in a region adjacent the sagging surface, and
attaching the ferroelectric material to the substrate comprises attaching the ferroelectric material to the sagging surface.

20. The method of claim 17, wherein:
the substrate comprises more than one material with mismatched coefficients of thermal expansion, and the substrate is configured to change shape in response to changes in temperature; and
elastically deforming the substrate comprises changing the temperature of the substrate so that it changes shape.

21. A method of generating electrical power using a transducer, wherein:
the transducer comprises:
a substrate;
a ferroelectric element adhered to the substrate;
a first and second electrode in electrical contact with the ferroelectric element and arranged to receive charge from resulting from ferroelectric domain switching of the ferroelectric element in response to mechanical loading of the transducer;
and the ferroelectric element is partially polarised and under residual intrinsic stress, so that a mechanical load cycle imposed on the transducer results in a reversible cycle of ferroelectric domain switching;
and the method comprises:
applying a mechanical load cycle to the transducer so as to generate electrical power into an electrical load by ferroelastic domain switching.

22. The method of claim 21, wherein the mechanical load cycle comprises a repolarisation phase in which the ferroelectric element becomes more polarised, and wherein the method does not include applying an electrical bias field during the repolarisation phase.

23-25. (canceled)
